(19) United States
(12) Patent Application Publication
(10) Pub. No.: US 2020/0387076 A1
(43) Pub. Date: Dec. 10, 2020

(54) Optical Measurement Method and Sensor Apparatus

(71) Applicant: ASML Netherlands B.V., Veldhoven (NL)

(72) Inventors: Joris Maria Gerardus LOOMAN, Mook (NL); Theodorus Franciscus Emilius Maria OVERES, Eindhoven (NL); Wouter Joep ENGELEN, Eindhoven (NL)

(73) Assignee: ASML Netherlands B.V., Veldhoven (NI)

(21) Appl. No.: 16/959,715

(22) PCT Filed: Dec. 10, 2018
(86) PCT No.: PCT/EP2018/084099

§ 371 Date: Jul. 2, 2020

(30) Foreign Application Priority Data
Jan. 4, 2018 (EP) 18150345.9

(51) Int. Cl. G03F 7/20

(52) U.S. Cl. CPC G03F 7/70891; G03F 7/7085; G03F 7/706

(57) ABSTRACT

An optical measurement method using an optical sensor apparatus (15), the optical sensor apparatus comprising an optical element (20) comprising a mark (22) configured to selectively transmit incident radiation (24), a photodetector (26) configured to receive radiation transmitted by the mark and provide an output signal that is indicative of the received radiation, and a support (30) which supports the optical element and is in thermal contact with the optical element. A thermal conductivity of the support is greater than a thermal conductivity of the optical element and a coefficient of thermal expansion of the support is greater than a coefficient of thermal expansion of the optical element. The method comprises performing a first measurement using the optical sensor apparatus, the first measurement including illuminating the mark with radiation. The temperature of the optical element changes during the first measurement. The temperature of the support is substantially constant throughout the first measurement.

### CROSS-REFERENCE TO RELATED APPLICATIONS

This application claims priority of EP application 18150345.9 which was filed on Jan. 4, 2018 and which is incorporated herein in its entirety by reference.

### FIELD

The present invention relates to an optical measurement method and an optical sensor apparatus suitable for use in a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Optical sensor apparatus have a wide variety of applications in lithography such as, for example, determining an alignment between two or more parts of the lithographic apparatus, determining lithographic errors such as overlay errors and/or focus errors, determining optical aberrations present in a projection system of the lithographic apparatus, etc. During a measurement components of known optical sensor apparatus undergo a non-ambient heat exchange with the surrounding environment (e.g. via the absorption of radiative energy) and experience a change in temperature. The change in temperature experienced by the components of the optical sensor apparatus causes thermal deformation of those components. Thermal deformation of components of the optical sensor apparatus may negatively affect a reproducibility and/or an accuracy of measurements performed using the optical sensor apparatus. It is desirable to provide an optical sensor apparatus that obviates or mitigates one or more problems of the prior art whether identified herein or elsewhere.

### SUMMARY

According to a first aspect of the invention, there is provided an optical measurement method using an optical sensor apparatus, the optical sensor apparatus comprising an optical element comprising a mark configured to selectively transmit incident radiation, a photodetector configured to receive radiation transmitted by the mark and provide an output signal that is indicative of the received radiation and, a support which supports the optical element and is in thermal contact with the optical element, wherein a thermal conductivity of the support is greater than a thermal conductivity of the optical element and wherein a coefficient of thermal expansion of the support is greater than a coefficient of thermal expansion of the optical element, the method comprising performing a first measurement using the optical sensor apparatus, the first measurement including illuminating the mark with radiation, wherein a temperature of the optical element changes during the first measurement and completing the first measurement, wherein the temperature of the support is substantially constant throughout the first measurement.

The optical measurement method advantageously enables reduced thermal deformation of the optical element during a measurement, resulting in greater accuracy. The optical measurement method also advantageously does not require a long period of time for the optical sensor apparatus to return to a desired initial temperature after completion of a measurement. Consequently the optical sensor apparatus is ready to be used again after a shorter period of time. This may advantageously result in a greater throughput for a lithographic apparatus. The temperature for each measurement is substantially equal which results in greater reproducibility between measurements performed according to the optical measurement method.

The phrase “substantially constant” is intended to indicate that any non-ambient thermal disturbances experienced by the optical element as a result of the measurement are not thermally conducted to the support until the measurement is complete.

The optical sensor apparatus may further comprise a heat exchanger in thermal communication with the support and the support is at a first temperature at the beginning of the first measurement, the method may further comprise waiting for a pre-determined amount of time after completion of the first measurement before performing a second measurement using the optical sensor apparatus, wherein the support substantially returns to the first temperature within the pre-determined amount of time.

The phrase “substantially returns to the first temperature” is intended to indicate that a difference between the temperature of the support after the pre-determined amount of time and the first temperature is small enough that any resulting thermal deformation of the optical sensor apparatus is smaller than a desired accuracy of the optical sensor apparatus. That is, the temperature of the support does not need to return to the exact same temperature as the first temperature after the pre-determined amount of time for the optical sensor apparatus to perform an acceptably accurate second measurement. A thermal deformation of the support resulting from a difference between the temperature of the support after the pre-determined amount of time and the first temperature may be small enough that the inaccuracy introduced to the second measurement is negligible relative to the desired accuracy of the optical sensor apparatus. The desired accuracy of the optical sensor apparatus may vary between different uses of the optical sensor apparatus and/or different embodiments of the optical sensor apparatus.

The optical element may have a length which extends between a heat exchange area of the optical element and the support, and that length may be sufficiently long that the temperature of the support is substantially constant throughout the first measurement.

The optical element length which extends between the heat exchange area of the optical element and the support may be sufficiently short that the temperature of the support changes within 10 seconds of the first measurement being completed.

Performing a measurement may comprise cooling the optical element with a cooling apparatus before illuminating the mark with radiation.

Performing a measurement may comprise cooling the optical element with a cooling apparatus during illumination of the mark with radiation.

Performing a measurement may comprise cooling the optical element with a cooling apparatus after illuminating the mark with radiation.

The heat exchange area may comprise the mark.

The heat exchange area may comprise an area of the optical element upon which radiation is incident.

The heat exchange area may comprise regions of the optical element that are cooled by the cooling apparatus.

According to a second embodiment of the invention, there is provided an optical sensor apparatus comprising an optical element comprising a mark configured to selectively transmit incident radiation, a photodetector configured to receive radiation transmitted by the mark and provide an output signal that is indicative of the received radiation, and a support which supports the optical element and is in thermal contact with the optical element, wherein a thermal conductivity of the support is greater than a thermal conductivity of the optical element and wherein a coefficient of thermal expansion of the support is greater than a coefficient of thermal expansion of the optical element.

The coefficient of thermal expansion of the optical element may be less than or equal to half of the coefficient of thermal expansion of the support.

The coefficient of thermal expansion of the optical element may be less than or equal to a tenth of the coefficient of thermal expansion of the support.

The coefficient of thermal expansion of the optical element may be less than or equal to a hundredth of the coefficient of thermal expansion of the support.

The coefficient of thermal expansion of the optical element may be less than or equal to about 0.2×10⁻⁶ K⁻¹.

The optical element may be formed from at least one of the following materials: ULE®, Zerodur®, AZ and Cordierite.

The thermal conductivity of the support may be at least two times greater than the thermal conductivity of the optical element.

The thermal conductivity of the support may be at least ten times greater than the thermal conductivity of the optical element.

The thermal conductivity of the support may be at least one hundred times greater than the thermal conductivity of the optical element.

The thermal conductivity of the support may be at least 175 Wm⁻¹K⁻¹.

The support may be formed from a ceramic.

The ceramic may be Silicon infiltrated Silicon Carbide.

The support may be formed from a metal.

The metal may be Aluminium.

The support may be formed from a metal-ceramic.

The metal-ceramic may be AlSiC.

The optical sensor apparatus may further comprise a heat exchanger in thermal communication with the support.

According to a third aspect of the invention, there is provided a lithographic apparatus comprising an illumination system configured to condition a radiation beam; a support structure constructed to support a patterning device, the patterning device being capable of imparting the radiation beam with a pattern in its cross-section to form a patterned radiation beam, a substrate table constructed to hold a substrate, the substrate table being provided with an optical sensor apparatus, and a projection system configured to project the patterned radiation beam onto the substrate, wherein the optical sensor apparatus comprises an optical element comprising a mark configured to selectively transmit incident radiation, a photodetector configured to receive radiation transmitted by the mark and provide an output signal that is indicative of the received radiation, and a support which supports the optical element and is in thermal contact with the optical element, wherein a thermal conductivity of the support is greater than a thermal conductivity of the optical element and wherein a coefficient of thermal expansion of the support is greater than a coefficient of thermal expansion of the optical element.

The lithographic apparatus may further comprise a heat exchanger in thermal communication with the support.

### BRIEF DESCRIPTION OF THE DRAWINGS

Embodiments of the invention will now be described, by way of example only, with reference to the accompanying schematic drawings, in which:

FIG. 1 schematically depicts a lithographic system comprising a lithographic apparatus, a radiation source and an optical sensor apparatus according to an embodiment of the invention;

FIG. 2 schematically depicts the optical sensor apparatus of FIG. 1;

FIG. 3 schematically depicts an optical sensor apparatus according to another embodiment of the invention; and,

FIG. 4 shows a flowchart showing an optical measurement method using an optical sensor apparatus according to an embodiment of the invention.

### DETAILED DESCRIPTION

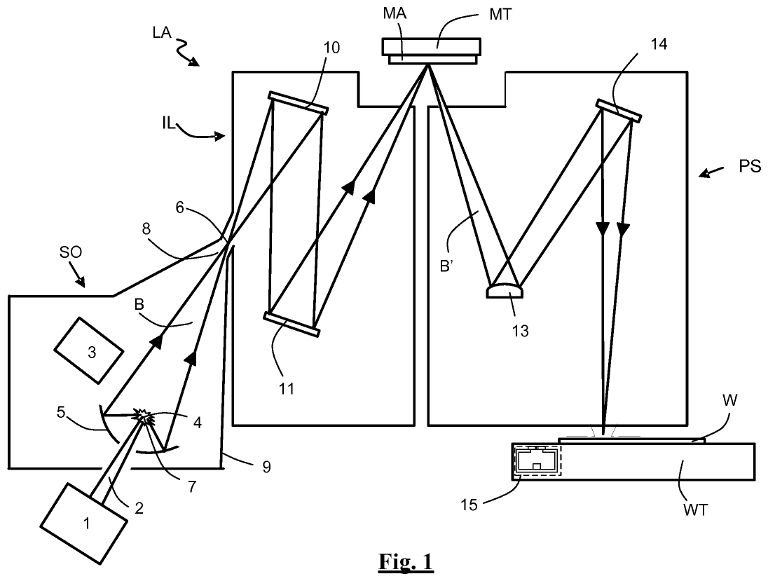

FIG. 1 shows a lithographic system comprising a radiation source SO, a lithographic apparatus LA and an optical sensor apparatus 15 according to an embodiment of the invention. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

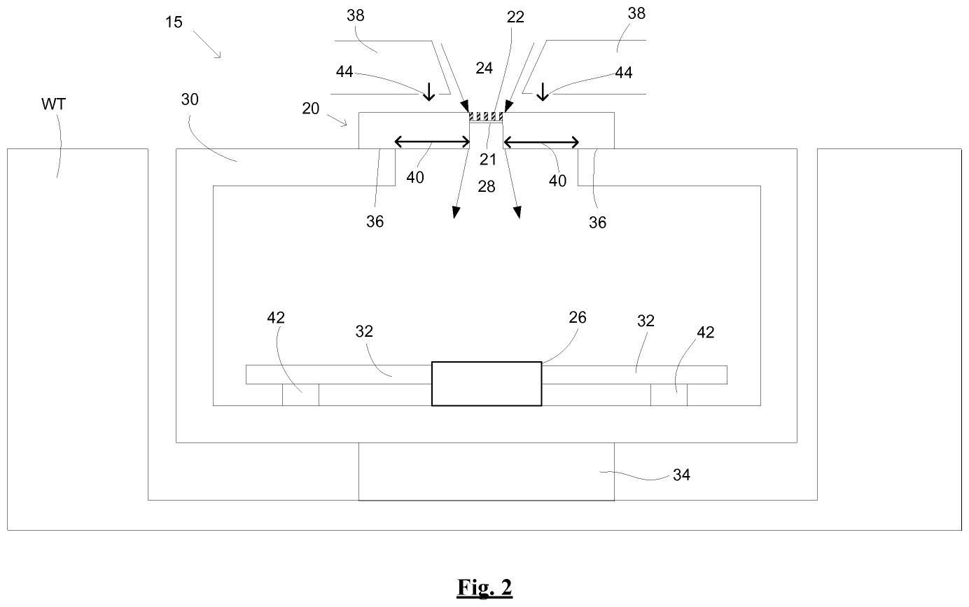

FIG. 2 schematically depicts the optical sensor apparatus 15 of FIG. 1. The optical sensor apparatus 15 comprises an optical element 20. The optical element 20 comprises a mark 22. The mark 22 is configured to selectively transmit incident radiation 24. For example, the mark 22 may comprise a grating or a checkerboard pattern formed on a membrane 21. The membrane 21 carrying the mark 22 may, for example, have a thickness of between about 100 nm and about 500 nm. The optical element 20 may have a thickness of between about 200 μm and about 700 μm. The optical sensor apparatus 15 further comprises a photodetector 26 configured to receive radiation 28 transmitted by the mark 22. A hole may exist in the optical element 20 directly beneath the membrane 21 carrying the mark 22 in order to allow radiation 28 transmitted by the mark 22 to reach the photodetector 26. The photodetector 26 is configured to provide an output signal that is indicative of the received radiation 28. The photodetector 26 may provide the output signal to electronics 32. The electronics 32 may, for example, take the form of a printed circuit board. The optical sensor apparatus 15 may comprise struts 42 configured to provide structural support to the photodetector 26, the electronics 32 and/or other components of the optical sensor apparatus 15. The optical sensor apparatus 15 further comprises a support 30 which supports the optical element 20 and is in thermal contact with the optical element 20. The optical element 20 and the support 30 may be connected to each other at a thermal contact area 36. The optical element 20 and the support 30 may be connected at the thermal contact area 36 by means of an adhesive layer. Alternatively the optical element 20 and the support 30 may be connected to each other via some other connection means such as, for example, a bolt or a clamp. The optical sensor apparatus 15 may further comprise a heat exchanger 34 in thermal communication with the support 30. The heat exchanger 34 may, for example, comprise a metal plate, such as steel, having conduits through which water having a controlled temperature passes.

The optical sensor apparatus 15 depicted in the example of FIG. 2 may be an integrated lens interferometer at scanner (ILIAS) sensor. An ILIAS sensor is an interferometric wavefront measurement system that may perform optical measurements on lens aberrations up to a high order. The photodetector 26 may comprise a camera. The camera may comprise a CCD array. U.S. Pat. No. 7,282,701B2, which is hereby incorporated by reference, discloses an ILIAS sensor that may be used to determine an intensity profile of radiation across a pupil plane of the projection system PS.

Alternatively, the optical sensor apparatus 15 depicted in the example of FIG. 2 may be a parallel lens interferometer at scanner (PARIS) sensor. A PARIS sensor comprises a shearing interferometer that is configured to measure a wavefront (i.e. a locus of points with the same phase). The shearing interferometer may comprise a diffraction grating mark 22 in an image plane of the projection system (i.e. at the substrate table WT) and a photodetector 26 arranged to detect an interference pattern in a plane that is conjugate to a pupil plane of the projection system PL. The interference pattern is related to the derivative of the phase of the radiation 24 with respect to a coordinate in the pupil plane in the shearing direction. The photodetector 26 may comprise a camera. The camera may comprise a CCD array. Determining aberrations which are caused by the projection system PL may comprise fitting the measurements which are made by the optical sensor apparatus 15 to Zernike polynomials in order to obtain Zernike coefficients. Different Zernike coefficients may provide information about different forms of aberration which are caused by the projection system PL. Stepping may be performed in the plane of the diffraction grating 22 and in a direction perpendicular to the scanning direction of the measurement. This stepping of the diffraction grating 22 effectively transforms phase variations into intensity variations, allowing phase information to be determined.

During a measurement the optical element 20 experiences a net gain of positive heat energy (i.e. the optical element 20 becomes hotter) or negative heat energy (i.e. the optical element 20 becomes cooler). This net gain of heat energy leads to a temperature change of the optical element 20. For example, performing a measurement using the optical sensor apparatus 15 includes illuminating the optical element 20 of the optical sensor apparatus 15 with radiation 24. The optical element 20 absorbs radiative energy 24 during the measurement which increases a temperature of the optical element 20. Other sources of positive heat energy and/or negative heat energy may affect a temperature of the optical element 20 during a measurement performed using the optical sensor apparatus 15. For example, the lithographic apparatus may comprise a cooling apparatus 38 configured to cool one or more areas adjacent a target area of a substrate undergoing a lithographic exposure. The cooling apparatus 38 may comprise gas outlets 44. The gas outlets 44 may provide a flow of cooled gas to one or more areas situated directly underneath the gas outlets 44. The cooling apparatus 38 may, for example, be configured to cool two areas at opposing sides of a radiation beam that is incident on the substrate. The cooling apparatus 38 may, for example, be configured to cool a first area that leads the radiation beam in a scanning direction of the lithographic apparatus and a second area that trails the radiation beam in the scanning direction. The cooling apparatus 38 may be configured to reduce thermal deformation of the substrate during the lithographic exposure. The cooling apparatus 38 may contribute to the net gain of positive heat energy or negative heat energy experienced by the optical element 20 during a measurement. The cooling apparatus 38 may remove more heat energy from the optical element 20 than is provided by the absorbed radiative energy 24. Where this is the case, the optical element 20 may experience a net thermal contraction during a measurement due to the effects of the cooling apparatus 38. Referring to FIG. 1, as a further example of a source of heat energy, the lithographic apparatus LA may comprise shielding gases such as Hydrogen. The shielding gases may be configured to reduce the amount of contamination generated by the substrate W (e.g. via outgassing) and the substrate table WT (e.g. via friction between moving parts) from reaching the projection system PS of the lithographic apparatus LA. Referring again to FIG. 2, these shielding gases may exchange heat with the optical element 20 and thereby cool or heat the optical element 20.

In known optical sensor apparatus, an optical element thermally conducts heat energy to a support during a measurement. Upon receiving heat energy from the optical element the support undergoes thermal deformations during the measurement. Thermal deformation of the support during a measurement may negatively affect a reproducibility and/or an accuracy of measurements performed using the known optical sensor apparatus. In addition, a significant amount of time may be required for known optical sensor apparatus to return to an initial temperature after a measurement is complete. For example, a known optical sensor apparatus may take between about 2 minutes and about 5 minutes to return to its initial temperature after a measurement is complete. This may negatively affect a throughput of known lithographic apparatus.

The initial temperature of the optical element and/or the support of known optical sensor apparatus may vary between different measurements if the heat energy gained during a first measurement is not directed away from the optical element and/or the support before beginning a second measurement. For example, the initial temperature of the optical element and/or the support may increase after repeated use because the heat energy gained by the optical element and/or the support during a measurement is not directed away from the optical element and/or the support before a subsequent measurement begins. The increase or decrease of the initial temperature of the optical element and/or the support may be of a larger scale when EUV radiation is used during the measurement and/or when the lithographic apparatus comprises a cooling apparatus which acts on the optical sensor apparatus. Having different initial temperatures at the beginning of different measurements may negatively affect an accuracy and/or reproducibility of measurements performed using known optical sensor apparatus. These problems are exacerbated when known optical sensor apparatus are used under vacuum conditions (e.g. when performing measurements in an EUV lithographic apparatus). This is because, under vacuum conditions, heat exchange between the optical element, the support and a heat exchanger is limited to conduction and radiation (i.e. convection is not possible under vacuum conditions). The lack of convection heat exchange under vacuum conditions results in a slower thermal system compared to when the optical sensor apparatus is under atmospheric conditions. That is, the optical sensor apparatus takes a longer amount of time to return to a desired initial temperature after a measurement has been performed. This is in turn may negatively affect a throughput of the lithographic apparatus.

Thermal deformations experienced by the optical element and/or the support may change the position and/or the size of the mark on the optical element relative to the photodetector and/or the other components of the lithographic apparatus. For example, a relative position between the mark on the optical element of a known optical sensor apparatus and an alignment mark on a reticle of the lithographic apparatus may change when the optical element and/or the support undergo thermal deformations during a measurement. Lithographic errors are then introduced to reticle alignment measurements performed using the known optical sensor apparatus. For example, known optical sensor apparatus comprise a silicon optical element. Silicon has a coefficient of thermal expansion of about 2.6×10⁻⁶ K⁻¹. The known optical element may undergo an increase in temperature of between about 3 mK and about 30 mK due to the absorption of radiative energy during a measurement. The known optical element may undergo a resulting thermal deformation of between about 0.1 nm and about 1 nm, thereby reducing an accuracy of the measurement.

Referring again to the embodiment of the invention depicted in FIG. 2, a coefficient of thermal expansion of the optical element 20 is less than a coefficient of thermal expansion of the support 30. Reducing the coefficient of thermal expansion of the optical element 20 reduces the thermal deformation experienced by the optical element 20 during a measurement. The coefficient of thermal expansion of the optical element 20 may be less than or equal to half of the coefficient of thermal expansion of the support 30. The coefficient of thermal expansion of the optical element 20 may be less than or equal to a tenth of the coefficient of thermal expansion of the support 30. The coefficient of thermal expansion of the optical element 20 may be less than or equal to a hundredth of the coefficient of thermal expansion of the support 30. The coefficient of thermal expansion of the optical element 20 may be less than or equal to about 0.2×10⁻⁶ K⁻¹. The optical element 20 may, for example, be formed from at least one of ULE ® available from Corning in the USA, Zerodur® available from Schott in Germany, AZ available from AGC in Japan and Cordierite available from Kyocera in Japan.

Providing an optical element 20 with a lower coefficient of thermal expansion than the support 30 may not provide a robust solution to the thermal deformation problems discussed above. Materials having a low coefficient of thermal expansion typically have a low thermal conductivity. Using materials having a low thermal conductivity results in a slower thermal system. That is, it takes longer for a change in heat to thermally conduct through and out of a material having a low thermal conductivity. The slower thermal system increases the amount of time required to wait between measurements before the temperature of the optical element returns to its initial temperature. This may negatively affect a throughput of the lithographic apparatus. If a sufficiently long delay isn't introduced between consecutive measurements, net heat will accumulate in the optical element after each measurement. As the number of measurements increases and the cumulative gain in heat energy increases, so too does the extent of the thermal deformations caused.

In order to compensate for the reduced thermal conductivity of the optical element 20, a thermal conductivity of the support 30 is greater than a thermal conductivity of the optical element 20. During a measurement the net positive or negative heat energy gained by the optical element 20 remains in the optical element 20. Once a measurement is complete the heat energy gained by the optical element 20 is thermally conducted by the optical element 20 to the support 30. Any non-ambient thermal disturbances experienced by the optical element 20 as a result of the measurement are not thermally conducted to the support 30 until the measurement is complete. Once the measurement is complete, heat energy may conduct from the optical element 20 to the support 30 via the thermal contact area 36. The support 30 may then thermally conduct the heat energy to the heat exchanger 34 before another measurement using the optical sensor apparatus 15 is due to take place. For example, a measurement using the optical sensor apparatus 15 may take up to about 0.7 seconds and the time taken for the heat energy gained by the optical element 20 during the measurement to begin to thermally conduct to the support 30 may be between about 0.7 seconds and about 1 second. The thermal conductivity of the support 30 may be at least two times greater than the thermal conductivity of the optical element 20. The thermal conductivity of the support 30 may be at least ten times greater than the thermal conductivity of the optical element 20. The thermal conductivity of the support 30 may be at least one hundred times greater than the thermal conductivity of the optical element 20. The support 30 may be formed from a ceramic. The ceramic may, for example, be Silicon infiltrated Silicon Carbide. Alternatively the ceramic may, for example, be Silicon Carbide. The support 30 may be formed from a metal. For example, the support 30 may be formed from aluminium. The support may be formed from a metal-ceramic. For example, the support may be formed from AlSiC. The thermal conductivity of the optical element 20 may be between about 1.3 Wm⁻¹K⁻¹ and about 1.5 Wm⁻¹K⁻¹. The thermal conductivity of the support 30 may be greater than or equal to about 175 Wm⁻¹K⁻¹.

A minimum length 40 of the optical element 20 through which heat energy must be thermally conducted in order to travel between a heat exchange area of the optical element 20 and the thermal contact area 36 with the support 30 may be determined. In general, the heat exchange area of the optical element 20 may be any area on the optical element 20 which receives a non-ambient heat flux during a measurement performed using the optical sensor apparatus 15. The heat exchange area of the optical element 20 may, for example, comprise the mark 22. The heat exchange area of the optical element 20 may, for example, comprise the area of the optical element 20 upon which radiation is incident. The area of the optical element 20 upon which radiation is incident may be greater than, equal to or smaller than the area of the mark 22. The heat exchange area of the optical element 20 may, for example, comprise any region of the optical element 20 that is cooled by a cooling apparatus 38 of the lithographic apparatus during the measurement. A minimum length 40 of the optical element 20 across which heat energy must be thermally conducted in order to travel between a heat exchange area and the support 30 may be calculated along one direction using the following equation:

$$Δ T = \frac{2 q \sqrt{\frac{α t}{π}}}{k} * {e}^{\frac{{x}^{2}}{4 α t}} - \frac{q x}{k} * erfc * ( \frac{x}{\sqrt{4 α t}} ) \qquad ( 1 )$$

where q is the heat flux incident on the optical element, α is the thermal diffusivity of the optical element, t is the duration of the measurement, k is the thermal conductivity of the optical element, x is a distance across which heat conducts, ΔT is a temperature change experienced by the optical element at the distance x and erfc is a complementary error function. Equation 1 may be used to calculate a distance from the heat exchange area to a location on the optical element 20 which experiences a temperature change of substantially zero for the duration of the measurement. The heat flux incident on the heat exchange area is known and the thermal diffusivity and thermal conductivity of the optical element 20 are known. The minimum length 40 of the optical element 20 may be calculated using a computer-aided method such as, for example, finite element analysis. Alternatively the minimum length 40 of the optical element 20 may be calculated by hand.

Referring again to FIG. 2, the minimum length 40 of the optical element 20 may be calculated in light of known characteristics of a measurement performed using the optical sensor apparatus 15. That is, the heat flux of the radiation 24 and the heat flux of a cooling apparatus 38 and/or shielding gas (not shown) across the duration of the measurement may be used to calculate the minimum length 40 such that the net positive or negative heat energy gained by the optical element 20 remains in the optical element 20 until the measurement is complete. That is, the optical element 20 has a length which extends between a heat exchange area of the optical element 20 and the support 30, and that length may be sufficiently long that the temperature of the support 30 is substantially constant throughout a measurement. Such measurement characteristics may be well known. For example, the measurement may have a duration of up to about 0.7 seconds and involve a radiation beam 24 providing a power of about 0.1 W to the optical element 20. The cooling apparatus 38 may begin cooling the optical element 20 about 0.05 seconds before the mark 22 is illuminated with radiation. The cooling apparatus 38 may provide cooling to the optical element for about 0.8 seconds. The cooling apparatus 38 may provide a cooling power of greater than about 0.3 W to the optical element 20 during the measurement. The cooling apparatus 38 may provide a cooling power of less than about 0.5 W to the optical element 20 during the measurement. Alternatively, the measurement characteristics may be measured. As a further alternative, the measurement characteristics may be determined using a computer-aided method such as finite element analysis.

Once a measurement performed by the optical sensor apparatus 15 is complete, the positive heat energy or negative heat energy gained by the optical element 20 may traverse the entirety of the minimum length 40 and begin to thermally conduct into the support 30 via the thermal contact area 36. The support 30 thermally conducts the heat energy from the optical element 20 to the heat exchanger 34 before another measurement is begun. The optical element length which extends between the heat exchange area of the optical element 20 and the support 30 may be sufficiently short that the temperature of the support 30 changes within 10 seconds of a measurement being completed. The optical element length which extends between the heat exchange area of the optical element 20 and the support 30 may be sufficiently short that the temperature of the support 30 changes within 5 seconds of a measurement being completed. Because the support 30 has a higher thermal conductivity than the optical element 20 it takes less time for the heat energy to conduct from the support 30 to the heat exchanger 34 than it takes for the heat energy to conduct from the optical element 20 to the support 30.

The amount of time between consecutive measurements may be equal to the amount of time between successive exposures of substrates in a lithographic apparatus. For example, the amount of time between consecutive measurements may be between about 30 s and about 50 s. The radiation 24 may, for example, provide a power of between about 10 mW and about 100 mW to the optical element 20 during a measurement performed using the optical sensor apparatus 15. The radiation 24 may be incident on the optical element 20 for between about 0.2 seconds and about 0.7 seconds. A cooling apparatus 38 of the lithographic apparatus may, for example, provide cooling to two 4 mm² areas either side of the radiation 24 incident on the optical element 20. The cooling provided by the cooling apparatus 38 may be greater than the heating provided by the radiation 24. For example, the cooling apparatus 38 may provide a cooling power of between about 0.3 W and about 0.6 W to the optical element 20. The cooling apparatus 38 may cool the optical element 20 for between about 0.5 seconds and about 0.8 seconds during a measurement. The temperature of the optical element 20 in the region illuminated by the radiation 24 may increase by about 0.5 K. The temperature of the optical element 20 in the regions cooled by the cooling apparatus 38 may decrease by about 2.5 K. The time taken for the non-ambient thermal disturbance experienced by the optical element 20 during the first measurement to thermally conduct to the support 30 may be greater than about 0.5 seconds. The time taken for the non-ambient thermal disturbance experienced by the optical element 20 during the first measurement to thermally conduct to the support 30 may be less than about 1 second. The time taken for the heat energy to thermally conduct from the support 30 to the heat exchanger 34 may, for example, be greater than about 15 seconds. The time taken for the heat energy to thermally conduct from the support 30 to the heat exchanger 34 may, for example, be less than about 45 seconds.

It will be appreciated that different lithographic systems utilise different types of optical measurement under different thermal conditions. As discussed above, the minimum length of the optical element 20 required to ensure that the temperature of the support 30 is substantially constant throughout a measurement may be calculated using computer aided methods such as finite element analysis or by hand, e.g. via equation 1. The minimum length 40 of the optical element 20 between the heat exchange area and the support 30 may, for example, be greater than about 1 cm. The minimum length 40 of the optical element 20 between the heat exchange area and the support 30 may, for example, be less than about 5 cm.

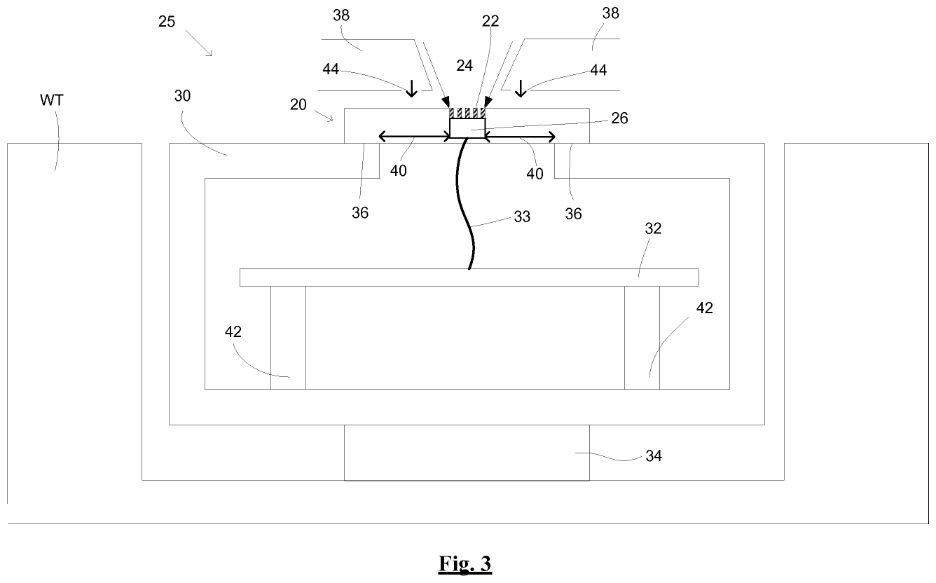

FIG. 3 schematically depicts an optical sensor apparatus 25 according to another embodiment of the invention. The optical sensor apparatus 25 comprises an optical element 20. The optical element 20 comprises a mark 22. The mark 22 is configured to selectively transmit incident radiation 24. For example, the mark 22 may comprise a grating. The optical element 20 may comprise other components, e.g. a diffuser. The optical element 20 may have a thickness of between about 200 μm and about 700 μm. The optical sensor apparatus 25 further comprises a photodetector 26 configured to receive radiation 28 transmitted by the mark 22. The photodetector 26 is configured to provide an output signal that is indicative of the received radiation 28. The photodetector may 26, for example, comprise a photodiode. In the example of FIG. 3, the photodetector 26 is located within the optical element 20 and directly beneath the mark 22. The photodetector 26 may provide the output signal to electronics 32 via an electrical connection 33 (e.g. wire). The electronics 32 may, for example, take the form of a printed circuit board. The optical sensor apparatus 25 may comprise struts 42 configured to provide structural support to the electronics 32 and/or other components of the optical sensor apparatus 25. The optical sensor apparatus 25 further comprises a support 30 which supports the optical element 20 and is in thermal contact with the optical element 20. The optical element 20 and the support 30 may be connected to each other at a thermal contact area 36. The optical element 20 and the support 30 may be connected at the thermal contact area 36 by means of an adhesive layer. Alternatively the optical element 20 and the support 30 may be connected to each other via some other connection means such as, for example, a bolt or a clamp. The optical sensor apparatus 25 may further comprise a heat exchanger 34 in thermal communication with the support 30. The heat exchanger 34 may, for example, comprise a metal plate, such as steel, having conduits through which water having a controlled temperature passes.

The optical sensor apparatus 25 depicted in FIG. 3 may be a transmission image sensor (TIS). The photodetector 26 may for example, comprise an EUV sensitive diode. U.S. Pat. No. 7,675,605, which is hereby incorporated by reference, discloses a TIS sensor that may be used to sense an aerial image in a lithographic apparatus.

With continued reference to FIG. 3, a coefficient of thermal expansion of the optical element 20 is less than a coefficient of thermal expansion of the support 30. The coefficient of thermal expansion of the optical element 20 may be less than or equal to half of the coefficient of thermal expansion of the support 30. The coefficient of thermal expansion of the optical element 20 may be less than or equal to a tenth of the coefficient of thermal expansion of the support 30. The coefficient of thermal expansion of the optical element 20 may be less than or equal to a hundredth of the coefficient of thermal expansion of the support 30. The coefficient of thermal expansion of the optical element 20 may be less than or equal to about 0.2×10⁻⁶ K⁻¹. The optical element 20 may, for example, be formed from at least one of ULE® available from Corning in the USA, Zerodur® available from Schott in Germany, AZ available from AGC in Japan and Cordierite available from Kyocera in Japan.

A thermal conductivity of the support 30 is greater than a thermal conductivity of the optical element 20. During a measurement the net positive or negative heat energy gained by the optical element 20 remains in the optical element 20. Once a measurement is complete the heat energy gained by the optical element 20 is thermally conducted by the optical element 20 to the support 30. Any non-ambient thermal disturbances experienced by the optical element 20 as a result of the measurement are not thermally conducted to the support 30 until the measurement is complete. Once the measurement is complete, heat energy may conduct from the optical element 20 to the support 30 via the thermal contact area 36. The support 30 may then thermally conduct the heat energy to the heat exchanger 34 before another measurement using the optical sensor apparatus 15 is due to take place.

The thermal conductivity of the support 30 may be at least two times greater than the thermal conductivity of the optical element 20. The thermal conductivity of the support 30 may be at least ten times greater than the thermal conductivity of the optical element 20. The thermal conductivity of the support 30 may be at least one hundred times greater than the thermal conductivity of the optical element 20. The thermal conductivity of the support 30 may be at least 175 Wm⁻¹K⁻¹. The support 30 may be formed from a ceramic. The ceramic may, for example, be Silicon infiltrated Silicon Carbide. Alternatively the ceramic may, for example, be Silicon Carbide. The support 30 may be formed from a metal. For example, the support 30 may be formed from aluminium. The support 30 may be formed from a metal-ceramic. For example, the support 30 may be formed from AlSiC. The thermal conductivity of the optical element 20 may be between about 1.3 Wm⁻¹K⁻¹ and about 1.5 Wm⁻¹K⁻¹.

Equation 1 may be applied to the embodiment of the invention depicted in FIG. 3 to determine a minimum length 40 of the optical element 20 across which heat energy must be thermally conducted in order to travel between a heat exchange area and the support 30. Equation 1 may be used to calculate a distance from the heat exchange area to a location on the optical element 20 which experiences a temperature change of substantially zero for the duration of the measurement. The minimum length 40 of the optical element 20 may be calculated using a computer-aided method such as, for example, finite element analysis. Alternatively the minimum length 40 of the optical element 20 may be calculated by hand. The minimum length 40 of the optical element 20 may be calculated in light of known characteristics of a measurement performed using the optical sensor apparatus 15.

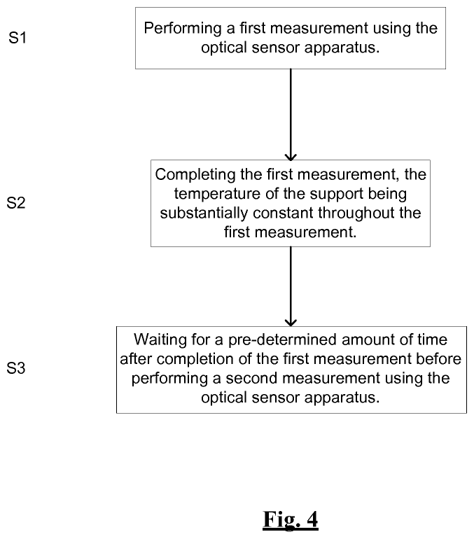

FIG. 4 shows a flowchart of a method of using the optical sensor apparatus of FIG. 2 or the optical sensor apparatus of FIG. 3 according to an embodiment of the invention. Step S1 of the method comprises performing a first measurement using the optical sensor apparatus, the first measurement including illuminating the mark with radiation. A temperature of the optical element changes during the first measurement. The optical element absorbs radiative energy and may also be cooled by the cooling apparatus and/or shielding gases during the first measurement. Step S2 of the method comprises completing the first measurement. The temperature of the support is substantially constant throughout the first measurement. This is because heat energy gained by the optical element remains in the optical element throughout the first measurement due to the lower thermal conductivity of the optical element. The support may be at a first temperature at the beginning of the first measurement. The first temperature may be equal to an ambient temperature of the lithographic apparatus. The first temperature may be less than or equal to 50 mK above an ambient temperature of the lithographic apparatus. The first temperature may be greater than or equal to 50 mK below the ambient temperature of the lithographic apparatus. Optional step S3 of the method comprises waiting for a pre-determined amount of time after completion of the first measurement before performing a second measurement using the optical sensor apparatus. The support substantially returns to the first temperature within the pre-determined amount of time. The higher thermal conductivity of the support enables dissipation of heat energy via thermal conduction between measurements. This allows a desired initial temperature of the optical sensor apparatus to be substantially reached before subsequent measurements begin. The optical sensor apparatus may, for example, return to within about 25 mK of the first temperature within the pre-determined amount of time.

Referring again to FIG. 2 and FIG. 3, performing a measurement using the optical sensor apparatus 15, 25 may comprise cooling the optical element 20 with a cooling apparatus 38 before illuminating the mark 22 with radiation 24. For example, the cooling apparatus 38 may begin cooling the optical element 20 about 50 ms before the mark 22 is illuminated with radiation 24. Performing a measurement using the optical sensor apparatus 15, 25 may comprise cooling the optical element 20 with a cooling apparatus 38 during illumination of the mark 22 with radiation 24. Performing a measurement using the optical sensor apparatus 15, 25 may comprise cooling the optical element 20 with a cooling apparatus 38 after illuminating the mark 22 with radiation 24. For example, the cooling apparatus 38 may cool the optical element 20 for about 50 ms after the mark 22 has been illuminated with radiation 24.

Although the optical sensor apparatus and method of use thereof has been described and depicted in the context of an EUV lithographic apparatus, embodiments of the invention may be used in other lithographic apparatus. For example, the optical sensor apparatus may form part of an ultraviolet (UV) lithographic apparatus configured to use UV radiation (e.g. having a wavelength of 365, 248, 193, 157 or 126 nm). The optical sensor apparatus and method of use thereof described herein may be particularly advantageous when utilized in an EUV lithographic apparatus. This is because EUV lithographic apparatus operate under vacuum conditions in which heat exchange between the optical element, the support and a heat exchanger is limited to conduction and radiation (i.e. convection is not possible under vacuum conditions). The optical sensor apparatus may reduce the extent to which the optical element thermally deforms during a measurement in an EUV lithographic apparatus despite convection cooling not being available.

The optical sensor apparatus may, for example, be used to perform a measurement once per substrate in a lot of substrates. The optical sensor apparatus may be used to perform a measurement once per lot of substrates. The optical sensor apparatus may be used with any desired frequency.

The optical sensor apparatus may be used to perform one or more alignment measurements in a dual-stage lithographic apparatus. The optical sensor apparatus may form part of a substrate table holding a first substrate. A first measurement may take place using the optical sensor apparatus before the first substrate undergoes a lithographic exposure. After the lithographic exposure, the first substrate table may be moved to a measurement side of the dual stage lithographic apparatus. The first substrate may be replaced by a second substrate on the measurement side. The second substrate may undergo one or more measurements on the measurement side. The first substrate table may then be moved back to the exposure side of the lithographic apparatus. A second measurement using the optical sensor apparatus may take place before the second substrate undergoes a lithographic exposure.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-29. (canceled)

30. An optical measurement method using an optical sensor apparatus comprising an optical element comprising a mark selectively transmitting incident radiation, a photodetector receiving radiation transmitted by the mark and provide an output signal that is indicative of the received radiation, and a support supporting the optical element and in thermal contact with the optical element, wherein a thermal conductivity of the support is greater than a thermal conductivity of the optical element and wherein a coefficient of thermal expansion of the support is greater than a coefficient of thermal expansion of the optical element, the method comprising:
performing a first measurement using the optical sensor apparatus, the first measurement including illuminating the mark with radiation, wherein a temperature of the optical element changes during the first measurement; and,
completing the first measurement, wherein the temperature of the support is substantially constant throughout the first measurement.

31. The method of claim 30, wherein the optical sensor apparatus further comprises a heat exchanger in thermal communication with the support and wherein the support is at a first temperature at the beginning of the first measurement, the method further comprising:
waiting for a pre-determined amount of time after completion of the first measurement before performing a second measurement using the optical sensor apparatus,
wherein the support substantially returns to the first temperature within the pre-determined amount of time.

32. The method of claim 30, wherein the optical element has a length which extends between a heat exchange area of the optical element and the support, wherein that length is sufficiently long that the temperature of the support is substantially constant throughout the first measurement.

33. The method of claim 32, wherein the optical element length which extends between the heat exchange area of the optical element and the support is sufficiently short that the temperature of the support changes within 10 seconds of the first measurement being completed.

34. The method of claim 30, wherein performing a measurement comprises cooling the optical element with a cooling apparatus before or during or after illuminating the mark with radiation.

35. The method of claim 32, wherein the heat exchange area comprises at least one of:
the mark;
an area of the optical element upon which radiation is incident; and
regions of the optical element that are cooled by the cooling apparatus.

36. An optical sensor apparatus comprising:
an optical element comprising a mark configured to selectively transmit incident radiation;
a photodetector configured to receive radiation transmitted by the mark and provide an output signal that is indicative of the received radiation; and
a support configured to support the optical element and is in thermal contact with the optical element,
wherein a thermal conductivity of the support is greater than a thermal conductivity of the optical element and
wherein a coefficient of thermal expansion of the support is greater than a coefficient of thermal expansion of the optical element.

37. The optical sensor apparatus of claim 36, wherein:
the coefficient of thermal expansion of the optical element is less than or equal to half of the coefficient of thermal expansion of the support;
the coefficient of thermal expansion of the optical element is less than or equal to a tenth of the coefficient of thermal expansion of the support; or
the coefficient of thermal expansion of the optical element is less than or equal to a hundredth of the coefficient of thermal expansion of the support.

38. The optical sensor apparatus of claim 36, wherein:
the coefficient of thermal expansion of the optical element is less than or equal to about 0.2×10⁻⁶ K⁻¹, or/and
the optical element is formed from ULE®, Zerodur®, AZ or Cordierite.

39. The optical sensor apparatus of claim 36, wherein:
the thermal conductivity of the support is at least two times greater than the thermal conductivity of the optical element; or
the thermal conductivity of the support is at least ten times greater than the thermal conductivity of the optical element.

40. The optical sensor apparatus of claim 36, wherein the thermal conductivity of the support is at least one hundred times greater than the thermal conductivity of the optical element.

41. The optical sensor apparatus of claim 36, wherein the thermal conductivity of the support is at least 175 Wm⁻¹K⁻¹.

42. The optical sensor apparatus of claim 36, wherein the support is formed from a ceramic.

43. The optical sensor apparatus of claim 42, wherein the ceramic is Silicon infiltrated Silicon Carbide.

44. The optical sensor apparatus of claim 36, wherein the support is formed from a metal.

45. The optical sensor apparatus of claim 44, wherein the metal is Aluminum.

46. The optical sensor apparatus of claim 36, wherein the support is formed from a metal-ceramic.

47. The optical sensor apparatus of claim 46, wherein the metal-ceramic is AlSiC.

48. The optical sensor apparatus of claim 36, further comprising a heat exchanger in thermal communication with the support.

49. A lithographic apparatus comprising:
an illumination system configured to condition a radiation beam;
a support structure constructed to support a patterning device, the patterning device being capable of imparting the radiation beam with a pattern in its cross-section to form a patterned radiation beam;
a substrate table constructed to hold a substrate, the substrate table being provided with an optical sensor apparatus, and,
a projection system configured to project the patterned radiation beam onto the substrate, \
wherein the optical sensor apparatus comprises:
an optical element comprising a mark configured to selectively transmit incident radiation;
a photodetector configured to receive radiation transmitted by the mark and provide an output signal that is indicative of the received radiation; and
a support which supports the optical element and is in thermal contact with the optical element,
wherein a thermal conductivity of the support is greater than a thermal conductivity of the optical element and
wherein a coefficient of thermal expansion of the support is greater than a coefficient of thermal expansion of the optical element.
